(19) United States
(12) Patent Application Publication
(10) Pub. No.: US 2011/0266676 A1
(43) Pub. Date: Nov. 3, 2011

(54) METHOD FOR FORMING INTERCONNECTION LINE AND SEMICONDUCTOR STRUCTURE

(75) Inventor: Atsunobu Isobayashi, Clifton Park, NY (US)

(73) Assignee: TOSHIBA AMERICA ELECTRONIC COMPONENTS, INC., Irvine, CA (US)

(21) Appl. No.: 12/772,294

(22) Filed: May 3, 2010

(51) Int. Cl. H01L 23/52; H01L 21/4763

(52) U.S. Cl. 257/751; 438/643; 257/E21.495; 257/E23.141

(57) ABSTRACT

A semiconductor structure is formed by placing a thin barrier metal layer in an interconnection trench or via in a manner such that the opening of the trench or via is not obstructed by an overhang that interferes with the placement of copper into the interconnection trench or via. The material for forming a copper interconnection line contains copper and manganese. Upon annealing, a manganese oxide layer is formed having barrier properties against copper diffusion.

### TECHNICAL FIELD

Described are semiconductor structures and methods for forming semiconductor structures having a metal layer barrier and manganese-based barrier for preventing diffusion of copper from copper-based interconnection lines.

### BACKGROUND

Modern semiconductor devices are characterized by decreasing size of each transistor element and thereby increasing the density of transistors within a device. In order to accommodate the decreasing scale of semiconductor devices, the dimensions of metallic interconnect lines forming electrical contacts with different regions of a semiconductor device are also reduced.

As the scale of semiconductor devices decreases, the efficiency of signal transmission along metallic interconnection lines has become a factor in the performance of semiconductor devices. In particular, the current densities carried by the metallic interconnection lines increase as the cross-sectional area of the metallic interconnection lines is made smaller. The reduced cross-sectional area of the metallic interconnection lines has a dual effect of increasing the parasitic line-to-line capacitance between neighboring metallic interconnection lines as well as increasing the resistance of the metallic interconnect lines, thereby slowing transmission speed. The decreasing mass of metallic interconnect lines also gives rise to complications from electromigration. At higher current densities, the increased kinetic energy of individual electrons can result in significant momentum transfer to individual metal atoms within the metallic interconnection line. A mass transfer in the direction of electron movement can occur overtime as the result of high current densities.

Aluminum has been the traditional primary component of metallic interconnection lines. However, copper is increasing used for its high conductivity and increased resistance to electromigration. Construction of semiconductor devices using copper-based interconnect lines requires adjustments to be made in semiconductor fabrication techniques. Copper is typically placed through a damascene (or inlaid) technique to fill recesses formed in a dielectric layer of a back-end-of-line (BEOL) structure. The damascene technique becomes increasingly problematic with decreasing device dimensions.

Further, copper from interconnect lines can rapidly diffuse into a surrounding dielectric layer. Even very minute quantities of copper diffused into the dielectric layer poison the dielectric layer and lead to unpredictable performance. Therefore, a barrier material is often used to line a trench and/or via to protect the surrounding dielectric layer from copper diffusion. Traditional materials can require a minimum thickness from about 6 to about 10 nm to be a sufficient barrier to copper diffusion. The necessary barrier thickness for effective prevention of copper diffusion is not affected by the decreasing scale of semiconductor devices. As such, a decreasing percentage of the trench and/or via volume is occupied by the copper interconnect line, since a portion of the volume must be used for the barrier material. The decreasing dimensions available for copper placement raises difficulties in the act of placing copper to form the interconnect lines as well as complications due to high resistance and electromigration.

### BRIEF DESCRIPTION OF DRAWINGS

FIG. 1 is an illustration of a process for manufacturing a semiconductor structure employing a barrier metal layer and an initial copper seeding step for forming a copper- or copper alloy-based interconnection line.

FIG. 2 is an illustration of a process for manufacturing a semiconductor structure employing a barrier metal layer and an adhesion layer for forming a copper- or copper alloy based-based interconnection line.

FIG. 3 is an illustration of a process for manufacturing a semiconductor structure using a reduced-thickness barrier metal layer and a copper- or copper alloy-based material having a manganese component in accordance with aspects of the innovations disclosed herein.

FIG. 4 shows a flow chart illustrating methods for forming a semiconductor structure with aspects of the innovations disclose herein.

### DETAILED DESCRIPTION

Material to form a copper- or copper alloy-based interconnection line is placed in an interconnection trench or via formed in a dielectric layer having a metal barrier layer of reduced thickness and an adhesion layer, where the material contains manganese and copper. The presence of a metal barrier layer of reduced width minimizes overhangs obscuring the opening of the interconnection trench or via formed in the dielectric layer that can create difficulties in forming a copper- or copper alloy-based interconnection line using damascene or dual-damascene techniques.

Following forming of the material to for the copper- or copper alloy-based interconnection line, the material is annealed to re-crystallize the copper or copper alloy to form the interconnection line. During annealing, manganese in the copper or copper alloy material is driven to the interface of the interconnection line and the adhesion layer, where manganese reacts with the oxide film present on the surface of the adhesion layer to form a manganese oxide layer. The manganese oxide layer contributes to blocking diffusion of copper from the interconnection line. As such, the semiconductor structure formed upon annealing has a metal barrier layer and a manganese oxide layer that together are sufficient to prevent copper diffusion.

Further, the manganese oxide layer has superior adhesion properties due to interaction with copper of the interconnection line. The minimization of overhang during placement of the copper- or copper alloy-based material for forming the interconnection line minimizes the occurrence of center line voiding as a result of the damascene process. The superior adhesion properties of the manganese oxide layer reduce the occurrence of random voiding during annealing to re-crystallize the copper or copper-based material forming the interconnection line.

Disclosed herein is a method for forming an interconnection line containing copper or a copper alloy by forming an interconnection trench or via in a dielectric layer and depositing a barrier metal layer on the surface of and within the interconnection trench or via. Then, an adhesion layer is placed on the surface of the barrier metal layer within the interconnection trench or via, wherein the adhesion layer has an oxide film present thereon. An interconnection material containing manganese and copper to form an interconnection line is formed within the interconnection trench or via. Annealing is performed on the semiconductor structure such that the manganese present in the interconnection material migrates to the interface between the adhesion layer and the interconnection line, wherein at least a portion of the migrating manganese oxidizes to form a manganese oxide layer with the manganese oxide layer formed interposed between the interconnection line and the adhesion layer.

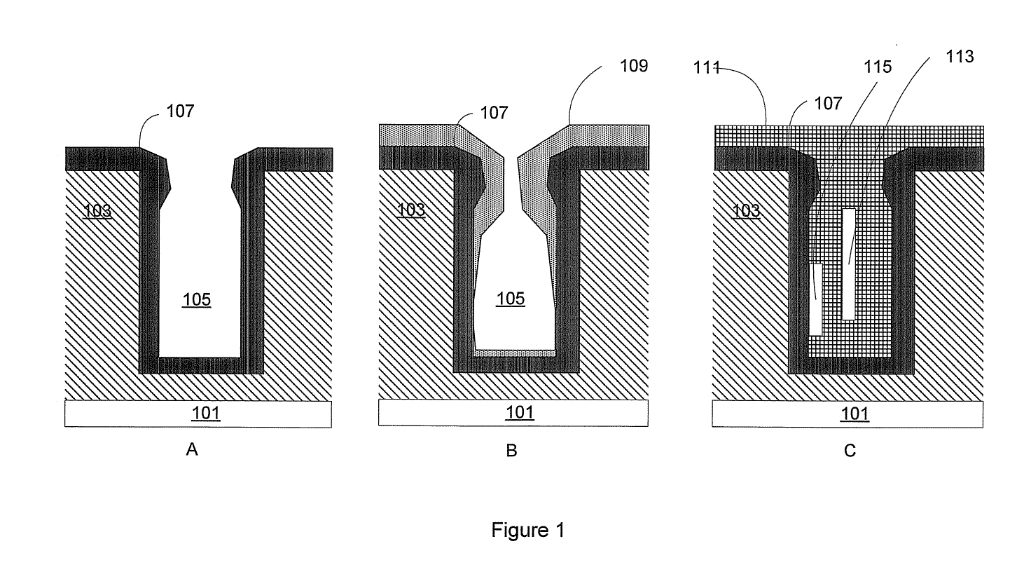

Current techniques for filling BEOL structures in small-scale devices are susceptible to forming voids and incomplete copper filling. A process flow for forming a BEOL structure includes the formation of transistor and/or capacitor circuit elements on a semiconductor substrate 101, as shown in FIG. 1A (not shown to scale). One or more metallization layers are formed by depositing a dielectric layer 103 by well-known chemical vapor deposition (CVD) techniques, spin-on techniques and the like. The dielectric layer 103 can be silicon dioxide or a low-k dielectric material. Low-k dielectric materials can be used to reduce parasitic capacitance between copper lines. A low-k dielectric material refers to any material having a dielectric constant less than the dielectric constant of silicon dioxide. The dielectric layer 103 is patterned by known photolithography and etching techniques to form a desired pattern of trenches and/or vias 105. A photomask can be placed over dielectric layer 103 followed by patterning the photomask and etching the underlying dielectric layer 103. Alternatively, dielectric materials that can be patterned directly by exposure to radiation are known. For simplicity, a single exemplary trench 105 is shown in FIG. 1A. Those skilled in the art will readily recognize that the innovations described herein are applicable to any pattern of trenches and vias. Some additional layers can be interposed between the dielectric layer 103 and the semiconductor substrate 101.

As shown in FIG. 1A, the trenches and/or vias 105 are lined with a barrier metal layer 107, which can be applied via well-known sputter deposition, CVD, atomic layer deposition (ALD) and the like. Suitable materials for the metal barrier layer include tantalum, tantalum nitride, titanium, titanium nitride and combinations thereof. In one embodiment, the width of the trenches and/or vias is from about 25 to about 60 nm. In another embodiment, the width of the trenches and/or vias is from about 30 to about 55 nm. In another embodiment, the width of the trenches and/or vias is from about 30 to about 50 nm. The average width or thickness of the barrier metal layer 107 can be from about 6 to about 15 nm.

Following formation of the barrier metal layer 107, the trench 105 is filled with a material containing at least 50% by weight of copper. The material containing at least 50% by weight of copper includes substantially pure copper, copper alloyed with other metals including manganese, and copper having a copper oxide component due to oxidation. While copper is typically deposited by electroplating, those skilled in the art will readily understand that methods other than electroplating can be used to fill-in the trench and/or via 105 so long as copper-containing material fills in the trenche and/or via 105 formed in the dielectric layer 103, for example, electroless plating and film formation using critical liquid.

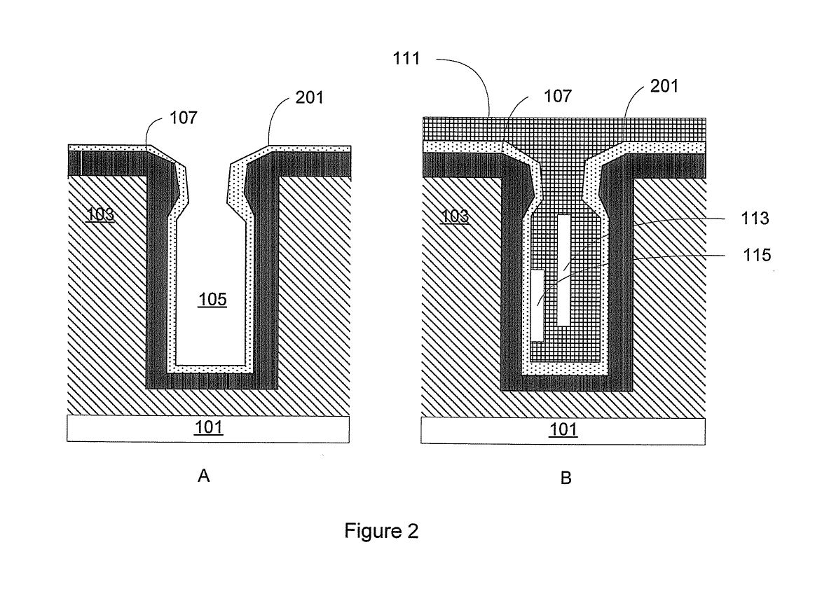

The barrier metal layer 107 is often an insufficient surface to directly support effective copper deposition by electroplating or other techniques. In FIG. 1B, the structure from FIG. 1A is prepared for copper electroplating by placing a copper seed layer 109 by sputter deposition or other appropriate techniques. In FIG. 2A, the structure from FIG. 1A is processed to have an adhesion layer 201 including one or more selected Co and Ru. The adhesion layer 201 can be placed by CVD, PVD, or other suitable deposition technique.

As shown in FIGS. 1B and 2A, the combination of a metal barrier layer 107 and the presence of any copper seed layer 109 and/or adhesion layer 201 causes a substantial narrowing of the opening of the trench 105 due to an overhang of material. Due to the narrowing of the trench 105 opening due to the overhang, a central line void 113 can develop during placement of copper- or copper-alloy based material 111 within the trench and/or via 105. As show in FIGS. 1C and 2B, central line voiding 113 forms a void that is filled by air or partial vacuum within the placed copper interconnection 111.

In addition to central voiding as a result of space restriction at the opening of trenches and/or vias 105, oxidation and poor adhesion can also result in additional voiding problems. Many materials used in the formation of semiconductor structures and/or devices are susceptible to the formation of an oxide film on the surfaces thereof. Copper can be easily oxidized in the presence of an oxygen atmosphere to produce an oxide film. The formation of a copper oxide film is exacerbated by heat treatments that are often employed during the fabrication of semiconductor structures. Oxide formation is accelerated by the numerous heat treatments employed during semiconductor manufacturing. Further, the material of adhesion layer 201 is also readily oxidized to form an oxide film of Co- and/or Ru-based adhesion layer 201. As will be described, the presence of oxide films on surfaces has the potential to lead to delirious effects on down-stream processing.

The native oxide layer formed on the copper- or copper alloy-based interconnection lines and the adhesion layer can interfere with adhesion between the interconnection line and the surrounding dielectric. The problem of adhesion is exacerbated by the increasingly common use of low-k materials in replace of silicon oxide as a preferred dielectric, which exhibit poorer adhesion characteristics. After electroplating the copper-based interconnection line, the structure is typically subjected to an annealing step to re-crystallize the copper or copper alloy of the interconnection line 111. Typical conditions for annealing include heating at a temperature from about 200 to about 400° C. for about 30 seconds to about 30 minutes. In another embodiment, annealing is performed from about 5 minutes to about 30 minutes. If a copper seed layer 109 is used, the copper seed layer 109 and the copper interconnection line 111 fuse, since both regions are copper based. During the annealing process, random voiding 115 can result due to poor adhesion between the copper-based interconnection line 111 and the adhesion layer 201 and/or the metal barrier layer 107 due to the presence of oxide films. There are unavoidable process gaps between the deposition of the copper seed layer 109 and/or the adhesion layer 201 and plating of the remaining copper or copper alloy to fill in the BEOL structure. During these process time delay periods, various surfaces are unavoidably susceptible to oxidation. The presence of oxide films lowers the adhesion of electroplated copper to allow for random voiding 115 to occur.

The innovations disclosed herein are now described with reference to the drawings, wherein like reference numerals are used to refer to like elements throughout. In the following description, for purposes of explanation, numerous specific details are set forth in order to provide a thorough understanding of the innovation. It may be evident, however, that the innovation can be practiced without these specific details. In other instances, well-known structures and devices are shown in block diagram form in order to facilitate describing the invention.

Those skilled in the art will recognize that well-known semiconductor fabrication techniques including depositing materials, masking, photolithography, etching, and implanting are useful in forming the described devices or structures. Deposition of materials for forming semiconductor structures can be by low pressure chemical vapor deposition, chemical vapor deposition, atomic layer deposition, and the like. Conserved reference numbers match like elements.

Terms, such as “on,” “above,” “below,” and “over,” used herein, are defined with respect to the plane defined by the surface of a semiconductor substrate. The terms “on,” “above,” “over,” etc. indicate that the subject element is farther away from the plane of the semiconductor substrate than another element referred to as a spatial reference. The term “below” and similar terms indicate that the subject element is closer to the plane of the semiconductor substrate than another element referred to as a spatial reference. The terms “on,” “above,” “below,” and “over,” etc. only indicate a relative spatial relationship and do not necessarily indicate that any particular elements are in physical contact. The term “interposed” between two layers indicates that described feature is located between a first layer and a second layer used for spatial reference; the descriptive term “interposed” does not require the feature interposed between two spatial reference layers to be in contact with any specific layer or feature. The preceding definitions apply throughout this document.

Specific embodiments in accordance with the innovations disclosed herein will be described. The occurrence of center line voiding can be addressed by increasing the width of the opening of the trench and/or via prior to electroplating or otherwise placing the copper or copper alloy interconnection line. However, a minimum total thickness of barrier material, for example 6 to 15 nm, is needed to serve as an effective barrier to copper diffusion. Narrowing of the opening of the trenches and/or vias is a consequence of reduced device size while having to maintain a necessary thickness of barrier material.

Copper diffusion is addressed by placing a barrier metal layer prior to placing (e.g., electroplating) the copper or copper alloy interconnection lines followed by formation of a second manganese oxide-based layer having barrier properties during a subsequent annealing act. That is, the barrier metal layer is formed prior to electroplating the copper or copper alloy interconnection line, as described above. Then, a second barrier material containing manganese oxide is formed after electroplating the copper or copper alloy interconnect.

The barrier metal layer is formed with a smaller than conventional thickness to avoid constricting the width of the opening of the trench and/or via with an overhang that can lead to center line voiding. However, a barrier metal layer having reduced thickness can be potentially insufficient to provide the necessary impediment to copper diffusion. The requirement for a sufficient barrier to prevent copper diffusion is addressed by forming an additional barrier layer (manganese oxide layer) after placing and/or electroplating the copper or copper alloy. The barrier metal layer and the later-formed manganese oxide layer together have a thickness sufficient to prevent copper diffusion. Through the innovations disclosed herein, copper or copper alloy interconnection lines can be formed without voiding while a barrier metal layer made from traditional materials is present. While several materials have barrier properties against copper diffusion, materials such as Ta, TaN, Ti, and/or TiN have superior properties in controlling copper diffusion over barrier systems not including Ta, TaN, Ti, and/or TiN.

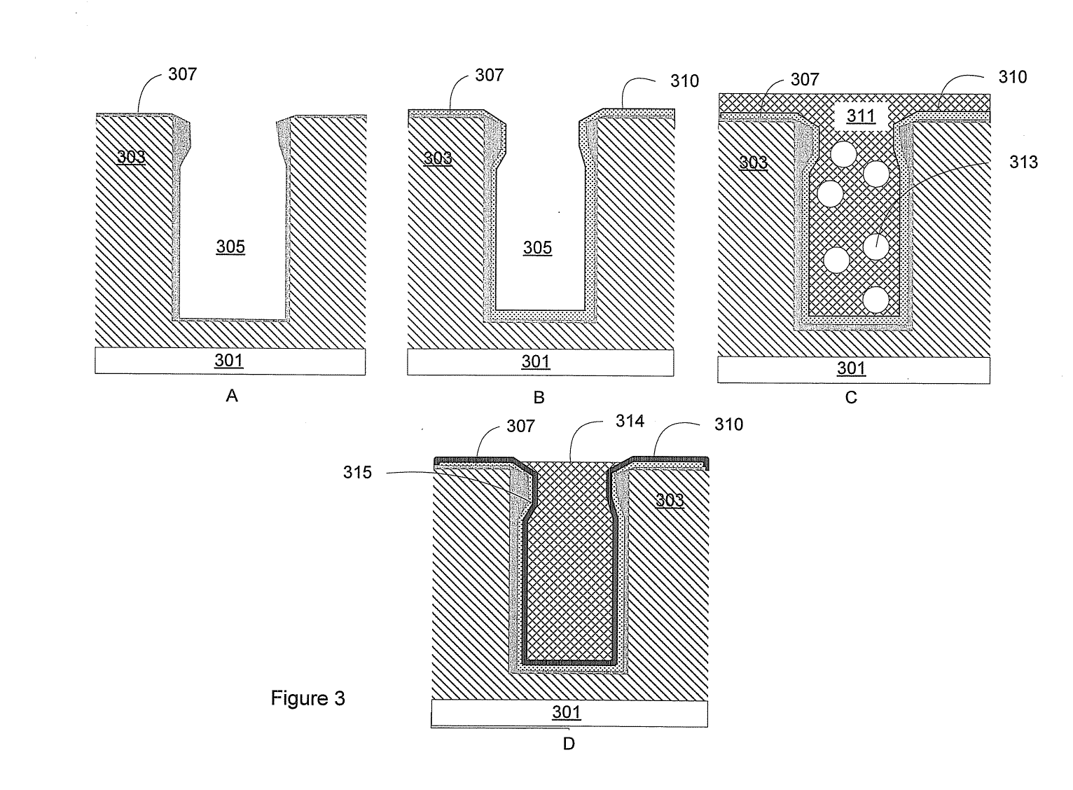

With reference to FIGS. 3A-D, embodiments of the innovations disclosed herein will be described. A dielectric layer 303 is placed over a semiconductor substrate 301 through deposition (CVD) techniques, spin-on techniques or the like. The semiconductor substrate 301 has appropriate transistor, capacitor, or other appropriate device structures formed thereon. Well-known techniques are used to form a pattern in the dielectric layer 303. Typically, photolithographic techniques are used to form a series of trenches and/or vias in the dielectric layer 303. Those skilled in the art will appreciate that the precise nature of the pattern formed in dielectric layer 303 is not critical for practicing the innovations described herein. For simplicity, an individual trench 305 is show in FIGS. 3A-D, which can be any appropriate trench or via feature formed for the purpose of placement of an interconnection line.

In FIG. 3A, a barrier metal layer 307 is formed by CVD or other compatible technique on the surface of the interconnection trench or via 305. The barrier metal layer 307 can contain one or more of Ta, TaN, Ti and TiN. In one embodiment, the average thickness of the barrier metal layer 307 is less than about 6 nm. In another embodiment, the average thickness of the barrier metal layer 307 is from about 2 nm to about 6 nm. In yet another embodiment, the average thickness of the barrier metal layer 307 is from about 3 nm to about 6 nm. The barrier metal 307 has an overhanged portion near the opening of the interconnection trench or via 305.

In FIG. 3B, an adhesion layer 310 is placed over the metal barrier layer 310. The adhesion layer 310 contains Co, Ru, or a combination thereof. In an embodiment, the adhesion layer includes a metal not that is not present in the barrier metal layer 307. Co is typically placed using CVD techniques while Ru can be placed using either CVD or physical vapor deposition (PVD) techniques. In one embodiment, the adhesion layer 310 has an average thickness from about 1 to about 4 nm in thickness. In another embodiment, the adhesion layer 310 has an average thickness from about 2 to about 4 nm in thickness. The adhesion layer 310 has an oxide film (not shown in the Figures) thereon. For example, in case Co is used as the adhesion layer 310, a thin cobalt oxide is formed on the cobalt adhesion layer 310. In case Ru is used as the adhesion layer 310, a thin ruthenium oxide is formed on the ruthenium oxide layer 310. The oxide film on the adhesion layer 310 can be continuously formed on the adhesion layer 310. Otherwise, the oxide film can be discontinuously formed on, dotted on or partially formed on the adhesion layer 310.

In another embodiment, a copper seed layer (not shown) is deposited by sputtering prior to electroplating the remaining mass of the copper or copper alloy interconnection line. The copper seed layer contains at least 50% by weight copper and can contain manganese. In one embodiment, the copper or copper alloy seed layer contains from about 0.5 to about 8 percent by weight of Mn. In another embodiment, the copper or copper alloy seed layer contains from about 1 to about 4 percent by weight Mn. In yet another embodiment, the copper or copper alloy seed layer does not contain Mn. If a copper seed layer having manganese is used, the remaining mass of the copper- or copper alloy-based material for forming an interconnection line does not require a manganese component.

After placement of the adhesion layer 310 or an optional copper seed layer, the interconnection trench or via 305 is filled-in with a copper- or copper alloy-based material using electroplating techniques or other suitable techniques, as shown in FIG. 3C. The material used to form the electroplated copper or copper alloy interconnect contains at least 50% by weight of copper. In one embodiment, the copper or copper interconnect contains from about 0.5 to about 8 percent by weight of Mn 313. In another embodiment, the copper or copper alloy interconnect contains from about 1 to about 4 percent by weight Mn 313. The interconnection trench or via 305 is filled with a cooper-based material containing manganese, where the copper-based material containing manganese needs to fill a portion of the interconnection trench or via 305. A feature of the innovations disclosed herein is that a material comprising manganese and copper is placed in the interconnection trench or via 305 prior to an annealing act; the material can be placed as part of a copper seed layer by sputtering or by electroplating to fill the volume of the interconnection trench or via 305.

After electroplating to fill the interconnection trench or via 305, excess material deposited during the preceding electrochemical deposition process and any optional seed layer formed on the adhesion barrier 307 outside of the interconnection trench or via 305 can be removed to form an interconnection line 314 located within the interconnection trench or via 305, as shown in FIG. 3D. The removal of excess electroplated material is usually performed with well-known chemical mechanical polishing (CMP) processes.

Upon heating and annealing of the copper interconnection line, the any copper seed layer and the copper interconnection line fuse during annealing. At least a portion of Mn that was initially contained in a copper- or copper alloy-based material placed in the interconnection trench or via 305 is removed from the alloy solution during the annealing process. Mn diffuses to the surface of the copper or copper alloy interconnection line 314 and accumulates at the boundary between the copper or copper alloy interconnection line 314 and the adhesion layer 310. As mentioned, the metal of the adhesion layer 310 forms an oxide film during processing. Due to the strong reducing properties of Mn, the Mn metal becomes oxidized to MnOₓ upon interaction with the oxide film on the adhesion layer 310. The oxygen component of the MnOₓ layer originates from the oxidized surface of the adhesion layer 310. The final formed interconnection line 314 can contain a residual amount of Mn, as not all Mn needs to be removed from the copper- or copper alloy-based material upon annealing. In one embodiment, the variable x in the formula MnOₓ is from about 0.5 to about 3.5. In another embodiment, the variable x in the formula MnOₓ is from about 0.5 to about 2.

As a result of removal of Mn from the alloy solution forming the interconnection line 314 during annealing, a manganese oxide layer 315 accumulates on the surface of the adhesion layer 307 separating the barrier metal layer 307 from the copper or copper alloy interconnection line 314. The manganese oxide layer 315 has barrier properties against copper diffusion and contributes in the reduction of copper diffusion into the dielectric layer. In one embodiment, the manganese oxide layer 315 has an average thickness from about 1 to about 4 nm. In another embodiment, the manganese oxide layer 315 has an average thickness from about 2 to about 3 nm. In one embodiment, the manganese oxide layer 315 does not comprise silicon or silicon atoms. That is, there is a region interposed between the dielectric material 303 and the copper or copper alloy interconnection line 314 that does not contain silicon or a material containing silicon atoms. Such region devoid of silicon or a material containing silicon atoms is from about 1 to about 4 nm in average thickness in one embodiment. In other embodiment, the region devoid of silicon or a material containing silicon atoms is disposed between the adhesion layer 310 and the cooper or copper alloy interconnection 314 with an average thickness from about 1 to about 4 nm. In yet another embodiment, the region devoid of silicon or a material containing silicon atoms is disposed between the barrier metal layer 307 and the cooper or copper alloy interconnection line 314 with an average thickness from about 1 to about 4 nm.

By forming the manganese oxide layer 315 at a time after filling in the copper or copper alloy interconnection line 314, a thinner barrier metal layer 307 can be employed to address center line voiding during electroplating of the copper or copper alloy interconnection line 314. In addition, manganese oxide layer 315 is chemically stable and allows for good adhesion between MnOₓ and the copper of the interconnection line 314. As such, the innovations described herein alleviated the problem of random voiding as a result of poor adhesion.

In one embodiment, the copper or copper alloy interconnection line 314 does not contain voids having a volume greater than about 150 nm³. In another embodiment, after annealing of the copper or copper alloy interconnection line 314 does not contain voids having a volume greater than about 100 nm³. In yet another embodiment, the copper or copper alloy interconnection line 314 does not contain voids having a volume greater than about 50 nm³. In still another embodiment, the copper or copper alloy interconnection line 314 does not contain voids having a volume greater than about 25 nm³.

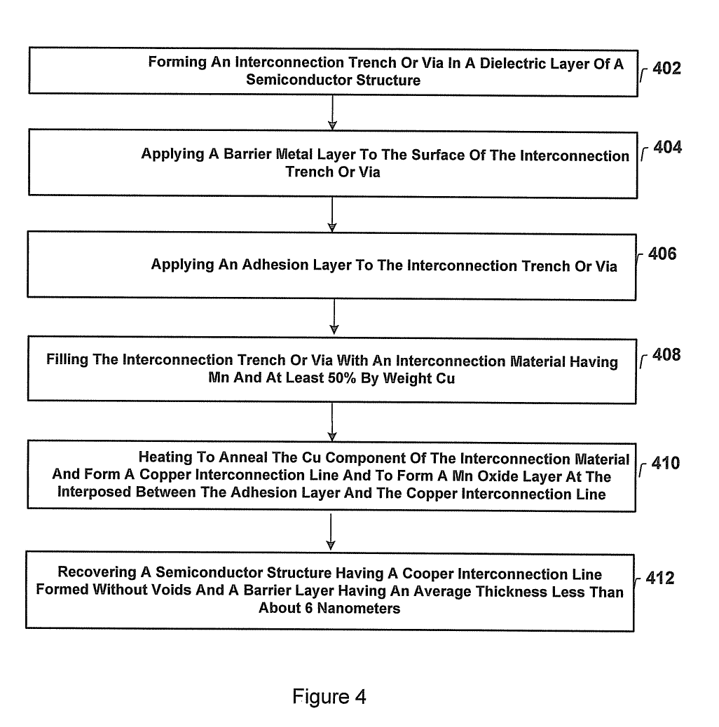

In order to fully describe the innovations disclosed herein, acts for forming a copper interconnection with decreased voiding will be described in reference in FIG. 4. In act 402, an interconnection trench or via is formed in a dielectric layer formed over a semiconductor substrate. The interconnection trench or via can be a trench and/or a via suitable for filling by a damascene or dual damascene process. The dielectric layer can be silicon oxide or a low dielectric (low k) material. In act 404, a barrier metal layer is applied to the surface of the interconnection trench or via, the barrier metal layer having an average thickness of less than about 6 nm. The barrier metal layer contains one or more of Ta, TaN, Ti, and TiN. In act 406, an adhesion layer is added to the surface of the interconnection trench or via. In act 408, the interconnection trench or via is filled with an interconnection material having manganese and at least 50% by weight of copper. Filling the interconnection trench or via with interconnection material can be done using electroplating, damascene, and/or dual damascene processes and can include forming a copper-containing seed layer by sputtering prior to filling the volume of the interconnection trench or via. The copper seed layer can contain manganese. In act 410, the semiconductor structure having an interconnection trench or via filled with the interconnection material is heated to anneal the copper contained in the interconnection material to form an interconnection line. During the annealing process, manganese in the interconnection material is driven to the interface between the barrier metal layer and the interconnection line where the manganese is oxidized to a manganese oxide by an oxide layer present of the surface of the adhesion layer. In act 412, a semiconductor structure having a copper-containing interconnection line free of voids with a barrier layer having an average thickness less than about 6 nm is recovered.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

What has been described above includes examples of the subject invention. It is, of course, not possible to describe every conceivable combination of components or methodologies for purposes of describing the subject invention, but one of ordinary skill in the art may recognize that many further combinations and permutations of the subject invention are possible. Accordingly, the subject invention is intended to embrace all such alterations, modifications and variations that fall within the spirit and scope of the appended claims. Furthermore, to the extent that the term “includes” and “involves” are used in either the detailed description or the claims, such terms are intended to be inclusive in a manner similar to the term “comprising” as “comprising” is interpreted when employed as a transitional word in a claim.

What is claimed is:

1. A method for forming an interconnection line, comprising:
forming an interconnection trench or via in a dielectric layer;
forming a barrier metal layer on the surface of the interconnection trench or via;
forming an adhesion layer on the surface of the barrier metal layer and within the interconnection trench or via, wherein the adhesion layer has an oxide film present thereon;
forming a material comprising manganese and at least 50% by weight of copper in the interconnection trench and via; and
annealing the material comprising manganese and copper to form an interconnection line such that at least a portion of the manganese in the material migrates to the interface of the interconnection line and the adhesion layer, wherein the adhesion layer oxidizes to form a manganese oxide layer, the manganese oxide layer formed interposed between the interconnection line and the adhesion layer.

2. The method of claim 1, wherein the barrier metal layer has an average thickness of less than about 6 nm.

3. The method of claim 1, wherein the barrier metal layer comprises one or more selected from the group consisting of Ta, TaN, Ti, and TiN.

4. The method of claim 1, wherein the interconnection material comprises from about 0.5 to about 8 percent by weight Mn.

5. The method of claim 1, wherein the average thickness of the manganese oxide layer is from about 1 to about 4 nm.

6. The method of claim 1, wherein annealing is performed by exposing the material comprising manganese and copper to a temperature from about 200 to about 400° C. for about 30 seconds or more.

7. The method of claim 1, wherein forming the material comprising manganese and copper in the interconnection trench or via comprises forming a seed layer comprising copper by sputtering.

8. The method of claim 1, wherein the oxide film of the adhesion layer is continuously formed on the adhesion layer.

9. The method of claim 1, wherein the oxide film of the adhesion layer is partially formed on the adhesion layer.

10. The method of claim 1, wherein the adhesion layer is a Co layer or a Ru layer.

11. The method of claim 1, wherein oxygen atoms or ions are supplied from the metal barrier layer oxide film to form the manganese oxide layer.

12. A semiconductor structure, comprising:
a dielectric material formed over a semiconductor substrate;
an interconnection trench or via formed in the dielectric material;
an interconnection line comprising copper located in the interconnection trench or via;
a barrier metal layer interposed between the dielectric material and the interconnection line, the barrier metal layer in contact with the dielectric material;
an adhesion layer interposed between the barrier metal layer and the interconnection line, the adhesion layer including a metal atom which is not in the barrier metal layer; and
a manganese oxide layer interposed between the adhesion layer and the interconnection line.

13. The semiconductor structure of claim 12, wherein the barrier metal layer has an average thickness of less than about 6 nm.

14. The semiconductor structure of claim 12, wherein the barrier metal layer comprises one or more selected from the group consisting of Ta, TaN, Ti, and TiN.

15. The semiconductor structure of claim 12, wherein the manganese oxide layer has an average thickness from about 1 to about 4 nm.

16. The semiconductor structure of claim 12, wherein the adhesion layer comprising one or more of Co and Ru.

17. The semiconductor structure of claim 11, wherein the barrier metal layer has an overhanged portion.

18. The semiconductor structure of claim 12, wherein the barrier metal layer has an average thickness of less than about 6 nm.

19. A method for forming an interconnection line, comprising:
providing a semiconductor structure having a semiconductor substrate, a dielectric layer formed over the semiconductor substrate, an interconnection trench or via formed within the dielectric layer, a barrier metal layer formed on the surface of and within the interconnection trench or via, an adhesion layer formed in the interconnection trench or via, and an oxide film present on the surface of the adhesion layer;
performing at least one of:
1) forming a copper seed layer in the interconnection trench or via; and
2) filling the interconnection trench or via with a copper-based material comprising copper to form an interconnection line,
wherein at least one of the copper seed layer and the copper-based material further comprises manganese;
heating in a temperature from about 200 to about 400° C. to form a copper-containing interconnection line and a magnesium oxide layer, the magnesium oxide layer formed by reaction of at least a portion of the manganese in at least one of the copper seed layer and the copper-based material with the oxide film on the adhesion layer, the magnesium oxide layer interposed between the barrier metal layer and the copper-containing interconnection line; and
recovering a semiconductor structure having the copper-containing interconnection line free from voids having a volume greater than about 25 nm³.

20. The method of claim 18, wherein the manganese oxide layer comprises MnOₓ, where x is from about 0.5 to about 3.5.

21. The method of claim 18, wherein the barrier metal layer has a thickness of less than about 6 nm, the barrier metal layer comprising one or more selected from the group consisting of Ta, TaN, Ti, and TiN.
